(19) United States
(12) Patent Application Publication
(10) Pub. No.: US 2025/0220953 A1
(43) Pub. Date: Jul. 3, 2025

(54) LDMOS EDGE TERMINATION FOR IMPROVED SAFE OPERATING AREA

(71) Applicant: Texas Instruments Incorporated, Dallas, TX (US)

(72) Inventor: Jingjing Chen, San Jose, CA (US)

(21) Appl. No.: 18/400,350

(22) Filed: Dec. 29, 2023

(51) Int. Cl. H01L 29/78; H01L 23/498

(52) U.S. Cl. CPC H10D 30/655; H01L 23/49827; H10D 30/601

(57) ABSTRACT

An electronic device includes a semiconductor layer with majority carriers of a first dopant type, a transistor finger structure extending along a first direction and including a drain finger and source fingers having majority carriers of a second type and laterally spaced apart from opposite sides of the drain finger along the second direction and a well region including majority carrier dopants of the first type in the semiconductor layer, the source fingers extending in respective portions of the well region, and the well region laterally extending around and encircling the finger structure.

### BACKGROUND

Laterally diffused metal-oxide semiconductor (LDMOS) transistors are drain extended transistors used in power switching circuits and other applications and can provide benefits for high voltage operation. However, inductively induced high di/dt in operation can raise the source potential higher than a buried layer to trigger a parasitic bipolar transistor action even if both the source and the buried layer are grounded. Lower or non-uniform voltage breakdown at the device edge can limit reverse bias snap back current capability due to the parasitic bipolar transistor triggering and reduce safe operating area (SOA) for the LDMOS transistors.

### SUMMARY

In one aspect, an electronic device includes a semiconductor layer having a side extending in a plane of orthogonal first and second directions and including majority carrier dopants of a first type, as well as a transistor finger structure and a well region. The transistor finger structure extends longitudinally along the first direction and includes a drain finger having opposite drain finger ends spaced apart from one another along the first direction in the semiconductor layer and including majority carrier dopants of a second type, and source fingers laterally spaced apart from opposite sides of the drain finger along the second direction in the semiconductor layer and including majority carrier dopants of the second type. The well region includes majority carrier dopants of the first type in the semiconductor layer, the source fingers extend in respective portions of the well region, and the well region laterally extends around and encircles the finger structure.

In another aspect, an electronic device includes a semiconductor layer having a side extending in a plane of orthogonal first and second directions and including majority carrier dopants of a first type, as well as a transistor finger structure, a well region, an implanted region, and a conductive contact. The transistor finger structure extends longitudinally along the first direction and includes a drain finger having opposite drain finger ends spaced apart from one another along the first direction in the semiconductor layer and including majority carrier dopants of a second type, and source fingers laterally spaced apart from opposite sides of the drain finger along the second direction in the semiconductor layer and including majority carrier dopants of the second type. The well region includes majority carrier dopants of the first type in the semiconductor layer, and the second well region laterally extends around and encircles the finger structure. The implanted region includes majority carrier dopants of the first type in an end portion of the well region spaced apart from the transistor finger structure along the first direction and the conductive contact extends from the implanted region to a metallization structure.

In a further aspect, an electronic device includes a semiconductor layer having a side extending in a plane of orthogonal first and second directions and including majority carrier dopants of a first type, a transistor finger structure, a deep trench isolation structure, and a deep well. The transistor finger structure extends longitudinally along the first direction and including a drain finger having opposite drain finger ends spaced apart from one another along the first direction in the semiconductor layer and including majority carrier dopants of a second type, and source fingers laterally spaced apart from opposite sides of the drain finger along the second direction in the semiconductor layer and including majority carrier dopants of the second type. The buried layer includes majority carrier dopants of a second type in the semiconductor layer and is spaced apart from the side of the semiconductor layer along a third direction that is orthogonal to the first and second directions. The deep trench isolation structure laterally surrounds the transistor finger structure in the semiconductor layer, and the deep trench isolation structure extends through the semiconductor layer to a semiconductor substrate along the third direction. The deep well laterally surrounds a portion of the deep trench isolation structure and adjacent a portion of the buried layer in the semiconductor layer, the deep well connected by a metallization structure to the source fingers.

### BRIEF DESCRIPTION OF THE DRAWINGS

FIG. 1 is a partial sectional end elevation view of an electronic device taken along line 1-1 of FIG. 1A.

FIG. 1A is a partial top plan view of the electronic device of FIG. 1.

FIG. 1B is a partial sectional side elevation view of the electronic device taken along line 1B-1B of FIG. 1A.

FIG. 1C is a partial top plan view of a dual transistor finger structure of the electronic device of FIGS. 1-1B surrounded by an isolation structure.

FIG. 1D is a partial top plan view of a first metallization level of the dual transistor finger structure of the electronic device of FIGS. 1-1C.

FIG. 1E is a partial top plan view of a second metallization level of the dual transistor finger structure of the electronic device of FIGS. 1-1D.

FIG. 1F is a partial top plan view of a third metallization level of the dual transistor finger structure of the electronic device of FIGS. 1-1E.

FIG. 1G is a partial sectional end elevation view of the electronic device taken along line 1G-1G of FIGS. 1C-1F.

FIG. 1H is a partial sectional end elevation view of the electronic device taken along line 1H-1H of FIGS. 1C-1F.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. In the following discussion and in the claims, the terms “including”, “includes”, “having”, “has”, “with”, or variants thereof are intended to be inclusive in a manner similar to the term “comprising”, and thus should be interpreted to mean “including, but not limited to”.

Unless otherwise stated, “about,” “approximately,” or “substantially” preceding a value means +/−10 percent of the stated value. One or more operational characteristics of various circuits, systems and/or components are hereinafter described in the context of functions which in some cases result from configuration and/or interconnection of various structures when circuitry is powered and operating. Drain extended transistors can include drain-extended NMOS (DENMOS), drain-extended PMOS (DEPMOS), and/or laterally diffused MOS (LDMOS) transistors, as well as groups of DENMOS and DEPMOS, referred to as complimentary drain extended MOS or DECMOS transistors. Described examples include doped regions of various semiconductor structures which may be characterized as p-doped and/or n-doped regions or portions and include regions that have majority carrier dopants of a particular type, such as n-type dopants or p-type dopants. One or more structures, features, aspects, components, etc., may be referred to herein as first, second, third, etc., such as first and second terminals, first, second, and third wells, etc., for ease of description in connection with a particular drawing, where such are not to be construed as limiting with respect to the claims. Various disclosed structures and methods of the present disclosure may be beneficially applied to manufacturing an electronic device such as an integrated circuit. While such examples may be expected to provide various improvements, no particular result is a requirement of the present disclosure unless explicitly recited in a particular claim.

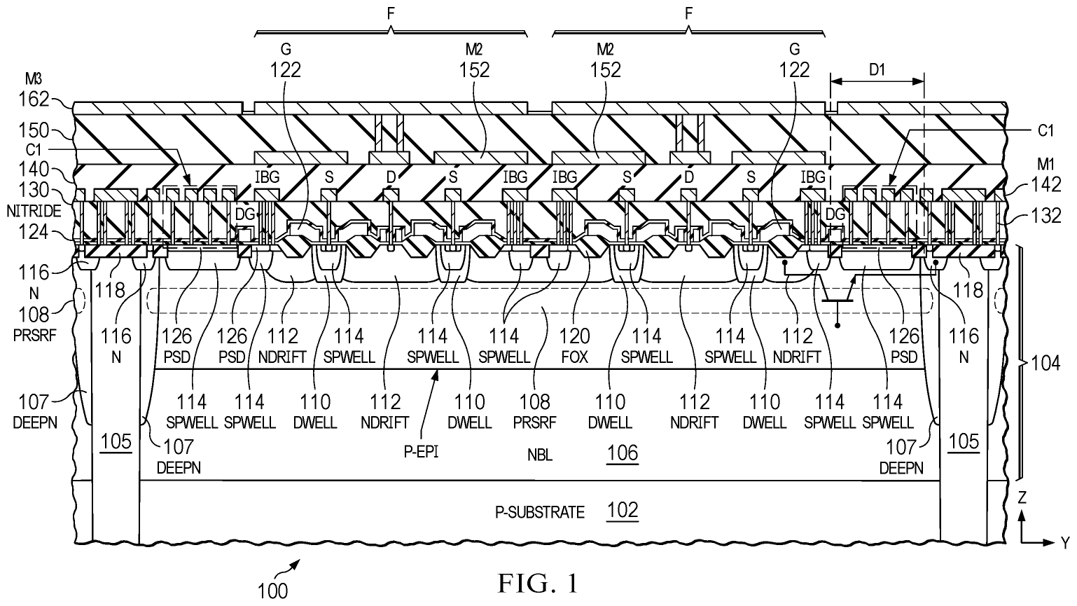

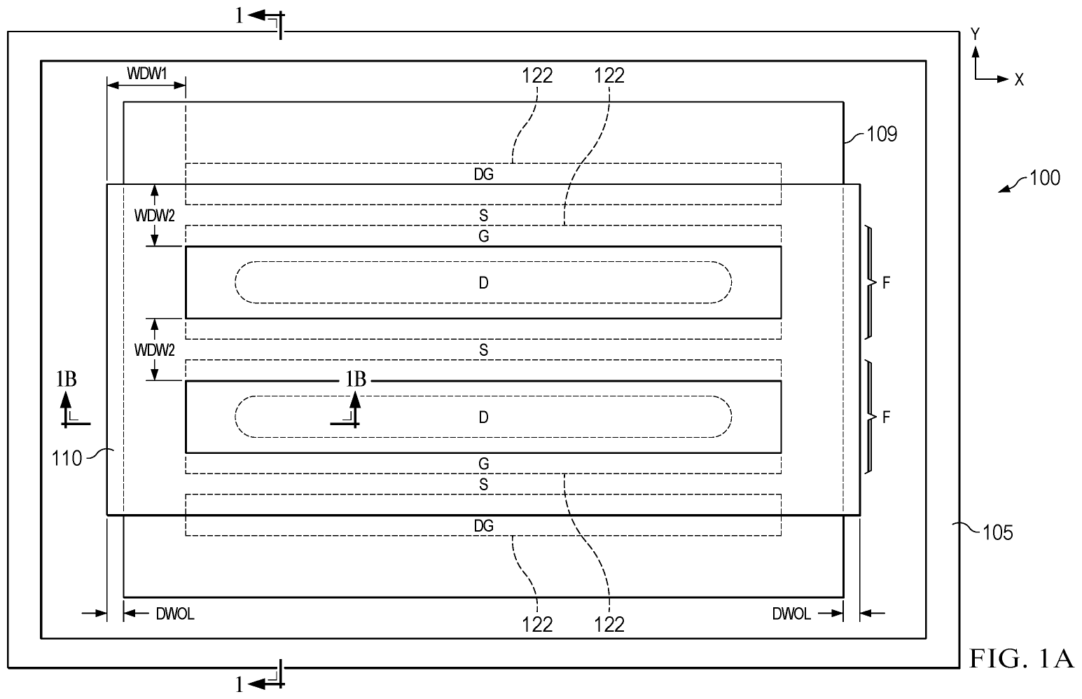

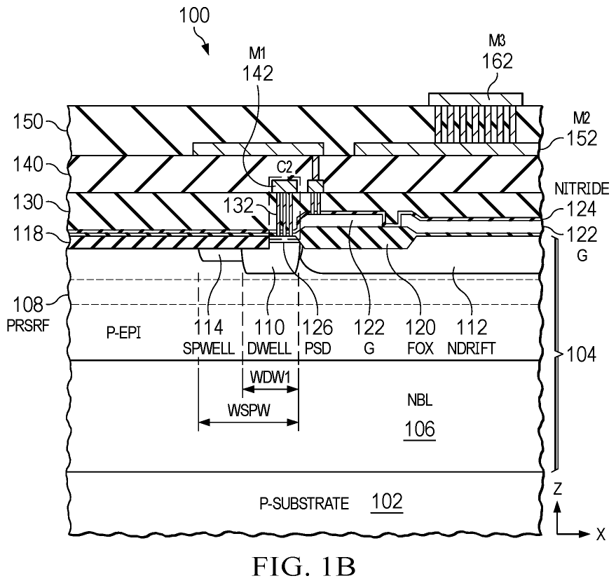

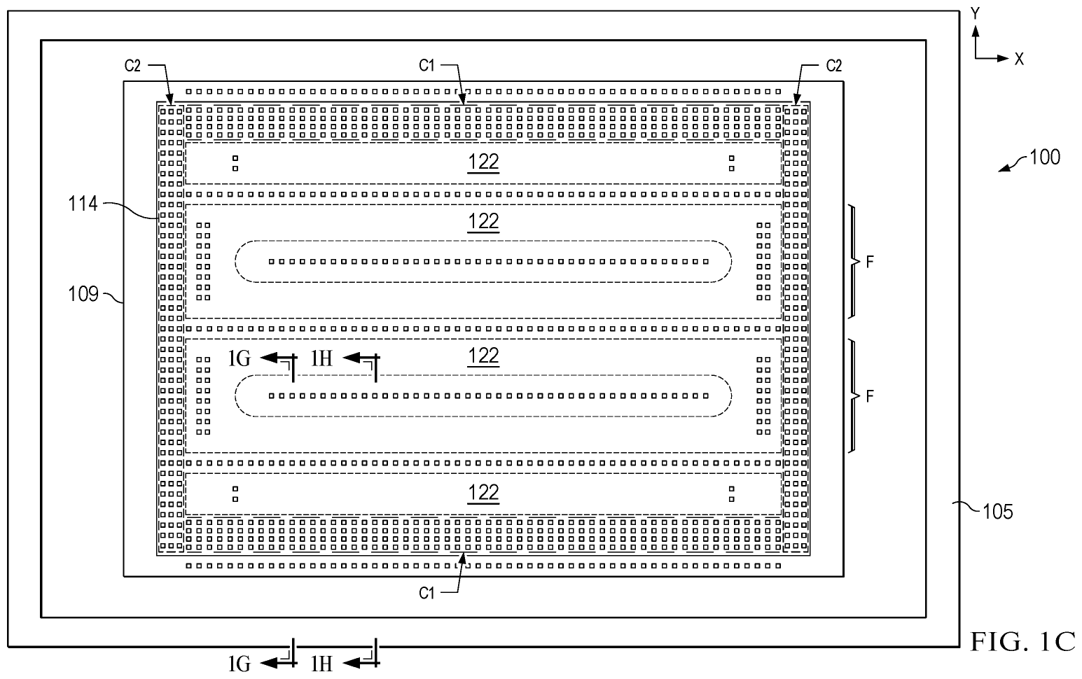

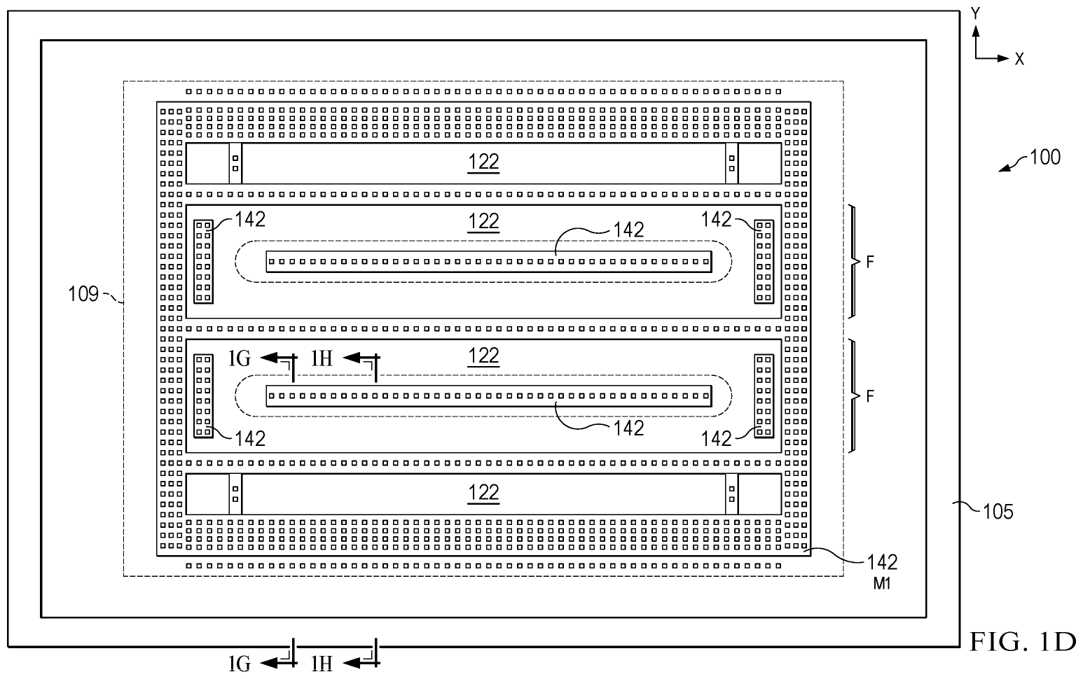

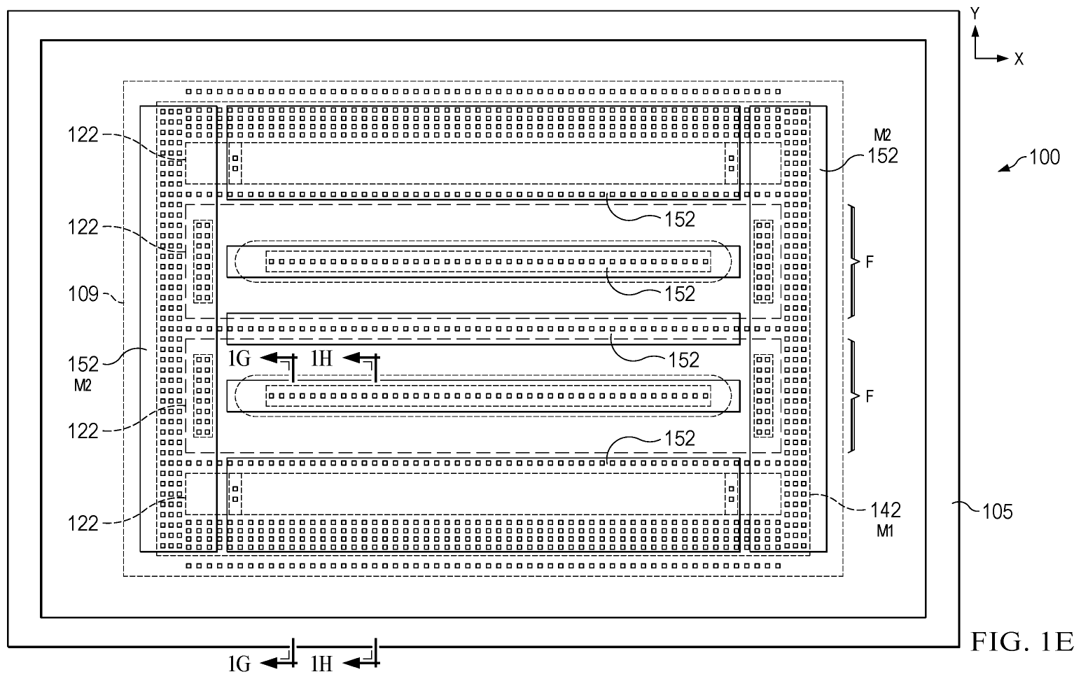

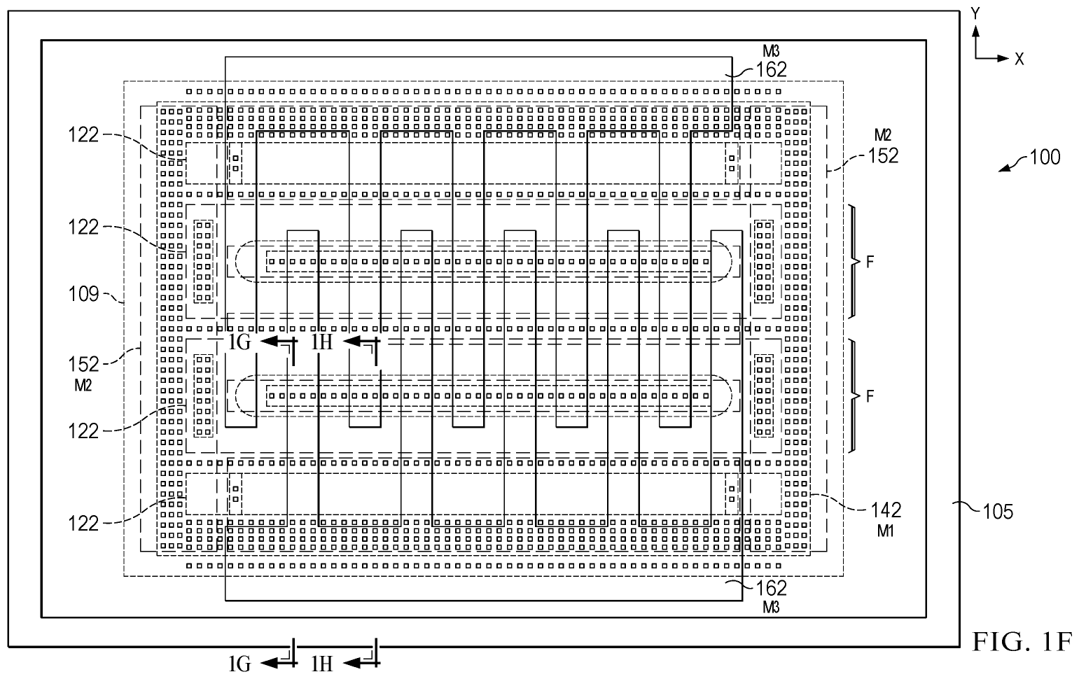

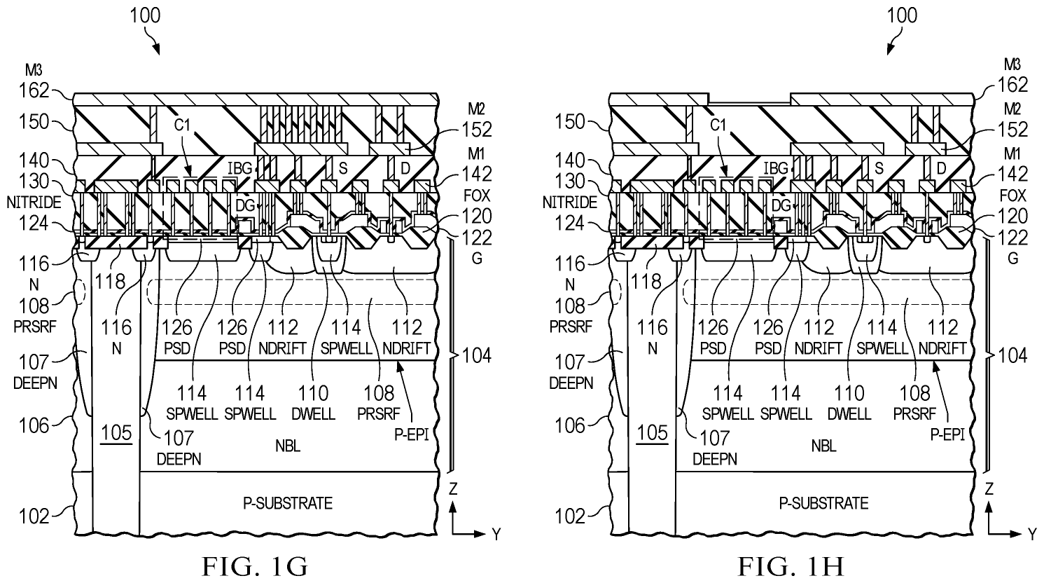

FIGS. 1-1H show an electronic device 100 with a semiconductor substrate 102 that is or includes silicon or other suitable semiconductor material and includes majority carrier dopants of a first type (e.g., p-type or P, labeled “P SUBSTRATE” in FIG. 1). The electronic device 100 includes an LDMOS transistor formed on and/or in a semiconductor layer 104 (e.g., epitaxial silicon, epitaxial semiconductor layer) that extends above the semiconductor substrate 102 as shown in FIGS. 1, 1B, 1G and 1H. The electronic device 100 is shown in an example three-dimensional space with a first direction X (e.g., FIGS. 1A-1F), a perpendicular (orthogonal) second direction Y (FIGS. 1, 1A, 1C-1H), and a third direction Z (FIGS, 1, 1B, 1G, and 1H) that is perpendicular (orthogonal) to the respective first and second directions X and Y. Structures or features along any two of these directions are orthogonal to one another. The semiconductor layer 104 has a top surface or side that extends in a plane of the first and second directions X and Y and an upper portion of the semiconductor layer 104 includes majority carrier dopants of the first type (e.g., p-type, labeled “P-EPI” in FIG. 1).

The LDMOS transistor has one or more transistor finger structures F (FIGS. 1, 1A, and 1C-1F). The illustrated example has two parallel drain-centered transistor finger structures F that are encircled by a deep trench isolation structure 105 that includes a trench structure (FIGS. 1, 1A, 1C-1H). In other implementations, any number of one or more transistor finger structures can be used. In one example, the trench structure 105 (or the deep trench isolation structure 105) includes a sidewall liner and is filled with doped polysilicon. The electronic device 100 includes a buried layer 106 (e.g., n-type, labeled “NBL” in FIGS. 1, 1B, 1G, and 1H) of the semiconductor layer 104. The buried layer 106 includes majority carrier dopants of an opposite second type (e.g., n-type or N). The deep trench isolation structure and the trench structure 105 thereof extends through the buried layer 106 of the semiconductor layer 104 and into the semiconductor substrate 102. A deep well 107 (FIGS. 1, 1G, and 1H) includes majority carrier dopants of the second type (e.g., labeled “DEEPN” in FIG. 1) and laterally surrounds a portion of the deep trench isolation structure 105 and has a portion that is adjacent a portion of the buried layer 106 in the semiconductor layer 104.

The respective transistor finger structures F extend longitudinally along the first direction X and include a drain finger D having opposite drain finger ends spaced apart from one another along the first direction X in the semiconductor layer 104. The respective drain fingers include majority carrier dopants of a second type N and are laterally central to the respective transistor finger structures F. The respective transistor finger structures also include two source fingers S laterally spaced apart from opposite sides of the corresponding drain finger D along the second direction Y in the semiconductor layer 104. The source fingers S includes majority carrier dopants of the second type N. As shown in FIG. 1G, the source fingers S are electrically connected by a metallization structure to the deep well 107.

The illustrated electronic device 100 also includes a reduced surface field implanted region 108 in the semiconductor layer 104 above the buried layer 106 (e.g., labeled “PRSRF in FIG. 1) with majority carriers of the first type (e.g., p-type). In some examples, the reduced surface field implanted region 108 includes profiled doping concentration to facilitate full reverse bias depletion of the drift region (e.g., drift region 112 described herein). In power switching circuit implementations, such as DC-DC converters, a high-side switch and a low-side switch may be fabricated as drain extended transistors. In the illustrated example, the respective transistor finger structures include an integrated back-gate terminal (e.g., labeled “IBG” in FIG. 1) that is electrically connected through the metallization structure to the source finger S. Moreover, the IBG is coupled to the deep well 107, the buried layer 106, and to the substrate 102 as shown in FIG. 1G.

As shown in FIGS. 1-1B, 1G and 1H, the electronic device 100 includes a well region 110 (e.g., labeled “DWELL” in FIG. 1) that includes majority carrier dopants of the first type (e.g., p- type) in the semiconductor layer 104. The transistor source fingers S extend in respective portions of the well region 110. In addition, and the well region 110 laterally extends around and encircles the finger structures F as shown in FIG. 1A. As further shown in FIGS. 1A and 1B, the lateral end of the well region 110 has a first width WDW1 along the first direction X and a lateral top portion of the well region 110 has a second width WDW2 (FIG. 1A) along the second direction Y. In one example, the first width WDW1 is greater than the second width WDW2. As further shown in FIGS. 1A and 1B, moreover, the well region 110 extends laterally outward along the first direction X beyond the outer boundary 109 of a semiconductor active region (where various elements of the LDMOS transistor are formed, such as source(S), drain (D), NDRIFT, etc., which may also be referred to as “moat” in some cases) by an overlap distance labeled DWOL in FIG. 1A.

As shown in FIGS. 1, 1B, 1G, and 1H, the respective transistor finger structures F of the LDMOS transistor also includes a drift region 112 with majority carrier dopants of the second type (e.g., n-type, labeled “NDRIFT” in FIG. 1). The LDMOS transistor can be combined with other components (not shown) in an implementation of the electronic device 100, for example, to form power switching or other circuits in which high voltage transistors are integrated with logic and other low voltage transistors on a single integrated circuit (IC). The extended drain structure of the transistor finger structures F can facilitate efficient operation as a low side switch in a switching power supply to provide low source-drain resistance (RDSON) during the on state, along with the ability to block or withstand high off-state voltages between the drain D and the source S or a gate G. The extended drain provides a relatively lightly doped drift region to extend the drain D away from the edge of the channel region. The drift region 112 can increase the reverse blocking voltage beyond the voltage rating of the gate oxide in a particular process.

As further shown in FIGS. 1, 1B, 1G, and 1H, the source fingers S in one example include a second well region 114 (e.g., shallow well region labeled “SPWELL” in FIG. 1) that extends in the respective portions of the well region 110 in the semiconductor layer 104. The second well region 114 includes majority carrier dopants of the first type (e.g., a shallow p-well with p-type carriers). The second well region 114 laterally extends around and encircles the finger structures F. As shown in FIG. 1B, the second well region 114 has an end portion that extends beyond a lateral end of the well region 110 along the first direction X. The end portion of the second well region 114 in one example has a width WSPW (FIG. 1B) that is wider than the first width WDW1 of the lateral end of the well region 110 along the first direction X (e.g., WSPW is greater than WDW1). As also shown in FIG. 1B, moreover, the well region 110 (DWELL) extends into the semiconductor layer 104 along the third direction Z and the well region 110 is deeper than the second well region 114 (SPWELL) along the third direction Z. As shown in FIG. 1, moreover, the deep trench isolation structure 105 and a portion of the deep well 107 are adjacent to a portion of the second well region 114 (SPWELL) along the second direction Y.

The electronic device 100 in one example includes shallow trench isolation (STI) structures 118 with insulator material formed in trenches that extend into the top side of the epitaxial semiconductor layer 104. The LDMOS transistor has an extended drain structure that includes an oxide structure 120 (e.g., field oxide structure, field oxide, labeled “FOX” in FIG. 1) that extends along the top side of the epitaxial semiconductor layer 104 and under polysilicon gate fingers 122 (e.g., labeled “G” in FIG. 1). Also shown in FIG. 1 are polysilicon dummy gate fingers (e.g., labeled “DG” in FIG. 1). In the illustrated example, the field oxide structure 120 is a local oxidation of silicon (LOCOS) structure. The field oxide 120 can provide a field gap for the laterally diffused extended drain. The example drain-centered transistor includes gate and source finger structures that extend laterally around the drain finger D, although not a requirement of all possible implementations. The oxide structure 120 in one example laterally encircles the drain finger D of the respective transistor finger structures F. As shown in FIG. 1, a nitride liner layer 124 extends along portions of the tops and sidewalls of the oxide structure 120 and the polysilicon gate and dummy gate structures 122 (e.g., labeled “NITRIDE” in FIG. 1).

As shown in FIGS. 1, 1B, 1G, and 1H, the LDMOS transistor also includes shallow first source drain implanted regions 126 (e.g., labeled “PSD” in FIG. 1). The first source drain implanted regions 126 include majority carrier dopants of the first type (e.g., p-type) with a concentration higher than that of the second well region 114-e.g., providing electrical coupling to the p-doped portion (P-EPI) of the semiconductor layer 104. In addition, the LDMOS transistor also includes shallow source drain implanted regions (not numerically designated) having majority carrier dopants of the second type (e.g., n-type)-e.g., providing source and drain of the LDMOS transistor.

The electronic device 100 also includes a multilevel metallization structure with a pre-metal dielectric (PMD) layer 130 over the top side of the epitaxial semiconductor layer 104 and the polysilicon structures 122. The multilevel metallization structure also includes tungsten or other conductive metal contacts 132 (FIG. 1), as well as a first interlevel or interlayer dielectric (ILD) layer 140 and patterned metal trace features 142 (or metallization structures 142) (e.g., labeled “M1” in FIG. 1, see also top view of FIG. 1D), as well as first metal vias (e.g., FIGS. 1B, 1G, and 1H, not numerically designated).

A second level of the metallization structure includes a second ILD layer 150 and patterned metal trace features 152 (e.g., labeled “M2” in FIG. 1, see also top view of FIG. 1E), as well as second metal vias (e.g., FIGS. 1, 1B, 1G and 1H, not numerically designated).

A final top (e.g., third) level of the metallization structure includes top side metal features 162 (e.g., labeled M3 in FIG. 1, see also top view of FIG. 1F), which form externally accessible terminals of a semiconductor die of the electronic device 100, such as die pads or bond pads suitable for wire bonding interconnections (not shown) and/or conductive metal pillars or posts configured for flip chip soldering to a lead frame or substrate (not shown).

The LDMOS transistor terminals include conductive contacts 132 (e.g., tungsten) that extend to the top side of the epitaxial semiconductor layer 104 and make electrical connection with respective source drain implanted regions to provide electrical interconnections of the transistor terminals to the metallization structure. The transistor finger structures F include p-type source drain implanted regions 126 as well as n-type source drain implanted regions in the upper portions of the second well region's 114 of the source fingers S and of the integrated back-gate terminals IBG. The drain finger D of the respective transistor finger structures F include n-type source drain implanted regions (not numerically designated) along the top side of the n-type drift region 112 that make electrical connection to the associated drain conductive contact 132. The interface between the source drain implanted regions and the associated tungsten contacts 132 can include conductive metal silicide (not shown).

As further shown in FIGS. 1A and 1C-1F, the LDMOS transistor includes polysilicon gate fingers 122 (e.g., labeled “G” in FIG. 1A) that laterally encircle or surround the corresponding transistor drain finger D, as well as polysilicon dummy gate fingers 122 (e.g., labeled “DG” in FIG. 1A) that are laterally spaced outward from the transistor finger structures F along the second direction Y. The deep trench isolation structure 105 and the deep well 107 in the semiconductor layer 104 laterally surround (e.g., encircle) the transistor finger structures F and the polysilicon gate fingers 122. As shown in FIGS. 1, 1G, and 1H, the deep trench isolation structure 105 extends through the semiconductor layer 104 to the semiconductor substrate 102 along the third direction Z. The deep trench isolation structure 105 and the deep well 107 are laterally spaced apart from the second well region 114 (SPWELL) along the first direction X by a distance D1 as shown in FIG. 1, where the distance D1 can be determined according to a breakdown voltage rating of the electronic device 100—e.g., the greater breakdown voltage ratings, the greater distances D1.

As best shown in FIGS. 1 and 1C, the electronic device 100 includes conductive contacts (e.g., tungsten contacts 132 of the initial layer of the metallization structure) with a first set of the contacts C1 connected to p-type source drain implanted regions 126 and associated portions of the shallow p-type well region 114 (SPWELL) laterally outward of the dummy gate polysilicon structures 122 (e.g., top and bottom in FIG. 1C), as well as a second set of contacts C2 laterally outward of the transistor finger structures F. As shown in FIG. 1B, a source drain implanted region 126 (PSD) is in the end portion of the second well region 114 and a conductive contact C2 132 extend from the source drain implanted region 126 to the metallization structure 142. As also shown in FIGS. 1 and 1D-1H, a second source drain implanted region in a lateral top portion (and a lateral bottom portion) of the second well region 114 is spaced apart from the transistor finger structure F along the second direction Y, and a second conductive contact C1 132 extends from the second source drain implanted region 126 to a metallization structure 142.

FIG. 1D shows portions of the first metal layer trace features 142 (M1), which includes connections to the first and second sets of contacts C1 and C2 to provide electrical connection of the metallization structure to the shallow second well region 114 (and to the well region 110 in some examples) around the periphery of the isolated portion of the semiconductor layer 104. As shown in FIG. 1D, a portion of the metallization structure 142 connects the second well region 114 to the dummy gate fingers of the LDMOS transistor. FIG. 1D shows that another portion of the metallization structure 142 are connected to the contacts to the polysilicon gate 122. Moreover, FIG. 1D shows that another portion of the metallization structure 142 are connected to the contacts to the drain fingers.

FIG. 1E further illustrates metal layer trace features 152 of the second level (M2), including trace features that provide connection to the drain and source fingers of the transistor (e.g., through respective first metal layer trace features 142). As described above, the deep well (DEEPN) 107 laterally surrounds a portion of the deep trench isolation structure 105, and the deep well 107 is adjacent to a portion of the buried layer 106 in the semiconductor layer 104. In addition, the deep well 107 is connected by the metallization structure to the source fingers S as shown in FIG. 1G. In this example, a first contact 132 to the metallization structure is connected to a portion of the deep well 107 along the top side of the semiconductor layer 104 and a second contact 132 of the metallization structure is connected to one of the source fingers S, with metal trace and via features of the metallization structure electrically connecting the source fingers S and the integrated back-gate fingers IBG to the deep well 107 and to the buried layer 106.

As shown in FIG. 1F, moreover, the third metal layer trace features 162 (M3) provide a pair of interleaved comb structures, each having a first portion that extends along the first direction X and second portions (e.g., comb fingers) that extend from the first portion along the second direction Y. In this example, the lower comb structure in FIG. 1F provides source and back-gate connections to the deep well 107 and the buried layer 106 as further shown in the sectional view of FIG. 1G. In addition, the upper comb structure in FIG. 1F provides drain finger interconnections to the metallization structure as further shown in the sectional view of FIG. 1H. Various metal via structures (e.g., metal vias connecting M1 to M2 metal layer trace features, metal vias connecting M2 to M3 metal layer trace features) are not explicitly illustrated in top plan view diagrams (e.g., in top plan view diagrams of FIGS. 1E and 1F), for clarity and simplicity.

The example LDMOS transistor including the transistor finger structures F in the electronic device 100 can significantly improve snapback current capability as well as breakdown voltage performance in operation of the transistor-e.g., due to reduction in reverse bias recovery time in some examples. For example, the second set of contacts C2 (which may be referred to as guard ring contacts) in FIG. 1C increases the snapback current capability of the LDMOS transistor-e.g., by facilitating reverse bias recovery. The metallization interconnection (through a combination of M1, M2, and/or M3 metal layer trace features) of the source fingers S (e.g., and the integrated back-gate fingers IBG) to the buried layer 106 in conjunction with the guard ring contacts C2 (FIG. 1C) provides significant advantages in terms of increased snapback current capability and improved breakdown voltage performance, such as approximately 25 percent improvement in maximum drain voltage that the transistors can support in some implementations.

Described examples provide extension of the well region 110 to encircle the transistor finger structures F (e.g., around the drain center active cell finger structures as shown in FIG. 1A above) alone or in combination with the guard ring contacts to the second well region 114 (e.g., first set of contacts C1, second set of contacts C2, or both sets of contacts C1, C2) around the dummy gate fingers DG and around the lateral ends. Also, the second well region 114 may be wider than the well region 110 (WSPW>WDW1 as shown in FIG. 1B) such that the transistors can support increased snapback current and thus, can have improved breakdown voltage performance.

Described examples and various implementations may also include further benefits associated with tailoring the spacing distance (D1 in FIG. 1) of the second well region 114 to the deep trench isolation structure 105 and the deep well 107, as well as the spacings and in the overlap between a shallow n-type third well region 116 and the field oxide 120 according to a device breakdown voltage rating for a given design.

Described examples and other implementations can advantageously provide metallization connections between the buried layer 106 and the source fingers S (e.g., and integrated back-gate fingers IBG) to further facilitate enhanced snapback current capabilities in operation of the transistor. These performance benefits and advantages may be separately achieved or further enhanced by extending the well region 110 past the outer boundary 109 of the semiconductor active region (which may be referred to as “moat”) along the first direction X (e.g., overlap distance DWOL in FIG. 1A, such as approximately 0.2 μm), with the second direction dimension overlapped or aligned with the edges of the respective polysilicon dummy gate fingers DG.

Certain implementations can also benefit from sufficient width of the second well region 114 along the first direction X (e.g., WSPW in FIG. 1B of approximately 2.0 microns for a 20 V breakdown voltage rating) with contacts 132 (e.g., contacts C2 in FIG. 1B) to the metallization structure 142. In certain implementations, moreover, snapback current improvement can be facilitated by a metallization structure providing a ring-shaped connection surrounding the transistor finger structures F (e.g., metallization structure 142 in FIG. 1D and associated contacts 132). The metallization structure provides low resistance interconnection of the source S and integrated back-gate fingers IBG to the buried layer 106—e.g., to accommodate inductively induced high di/dt while mitigating rising of the transistor source potential higher than a buried layer 106. In this manner, described example implementations may mitigate or avoid parasitic bipolar transistor triggering, such as a parasitic NPN bipolar transistor shown in dashed line in FIG. 1 with a collector formed by the n-type drift region 112, a p-type base formed by the p-doped portion of the epitaxial semiconductor layer 104, and an n-type collector formed by the n-type third well region 116.

The above-described benefits can be achieved by implementing one or more of the above-described features and aspects of the electronic device 100 to mitigate or prevent lateral bipolar transistor triggering, and provide increased and more uniform voltage breakdown performance, particularly at the device edges to facilitate reverse bias snapback current and improve safe operating area (SOA).

Modifications are possible in the described embodiments, and other embodiments are possible, within the scope of the claims.

The following is claimed:

1. An electronic device, comprising:
a semiconductor layer having a side extending in a plane of orthogonal first and second directions and including majority carrier dopants of a first type;
a transistor finger structure extending longitudinally along the first direction and including a drain finger having opposite drain finger ends spaced apart from one another along the first direction in the semiconductor layer and including majority carrier dopants of a second type, and source fingers laterally spaced apart from opposite sides of the drain finger along the second direction in the semiconductor layer and including majority carrier dopants of the second type; and
a well region including majority carrier dopants of the first type in the semiconductor layer, the source fingers extending in respective portions of the well region, and the well region laterally extending around and encircling the finger structure.

2. The electronic device of claim 1, wherein the source fingers comprise a second well region extending in the respective portions of the well region, the second well region including majority carrier dopants of the first type in the semiconductor layer, the second well region laterally extending around and encircling the finger structure, and the second well region having an end portion that extends beyond a lateral end of the well region along the first direction.

3. The electronic device of claim 2, wherein the lateral end of the well region has a first width along the first direction, and the end portion of the second well region is wider than the first width along the first direction.

4. The electronic device of claim 2, comprising an implanted region including majority carrier dopants of the first type in the end portion of the second well region, and a conductive contact extending from the implanted region to a metallization structure.

5. The electronic device of claim 4, comprising a second implanted region including majority carrier dopants of the first type in a lateral top portion of the second well region spaced apart from the transistor finger structure along the second direction, and a second conductive contact extending from the second implanted region to a metallization structure.

6. The electronic device of claim 2, comprising an implanted region including majority carrier dopants of the first type in a lateral top portion of the second well region spaced apart from the transistor finger structure along the second direction, and a conductive contact extending from the implanted region to a metallization structure.

7. The electronic device of claim 1, wherein a lateral end of the well region has a first width along the first direction, a lateral top portion of the well region has a second width along the second direction, and the first width is greater than the second width.

8. An electronic device, comprising:
a semiconductor layer having a side extending in a plane of orthogonal first and second directions and including majority carrier dopants of a first type;
a transistor finger structure extending longitudinally along the first direction and including a drain finger having opposite drain finger ends spaced apart from one another along the first direction in the semiconductor layer and including majority carrier dopants of a second type, and source fingers laterally spaced apart from opposite sides of the drain finger along the second direction in the semiconductor layer and including majority carrier dopants of the second type;
a well region including majority carrier dopants of the first type in the semiconductor layer, the second well region laterally extending around and encircling the finger structure;
an implanted region including majority carrier dopants of the first type in an end portion of the well region spaced apart from the transistor finger structure along the first direction; and
a conductive contact extending from the implanted region to a metallization structure.

9. The electronic device of claim 8, comprising a second implanted region including majority carrier dopants of the first type in a lateral top portion of the well region spaced apart from the transistor finger structure along the second direction, and a second conductive contact extending from the second implanted region to a metallization structure.

10. The electronic device of claim 8, wherein the source fingers extend in respective portions of a second well region including majority carrier dopants of the first type in the semiconductor layer.

11. The electronic device of claim 10, wherein the second well region extends into the semiconductor layer along a third direction that is orthogonal to the first and second directions, and the second well region is deeper than the well region along the third direction.

12. The electronic device of claim 8, comprising a deep trench isolation structure laterally surrounding the transistor finger structure in the semiconductor layer, the deep trench isolation structure extending through the semiconductor layer to a semiconductor substrate along a third direction that is orthogonal to the first and second directions, and the deep trench isolation structure laterally spaced apart from the well region along the first direction.

13. The electronic device of claim 12, wherein the deep trench isolation structure is adjacent to a portion of the well region along the second direction.

14. The electronic device of claim 13, comprising a second implanted region including majority carrier dopants of the first type in a lateral top portion of the well region spaced apart from the transistor finger structure along the second direction, and a second conductive contact extending from the second implanted region to a metallization structure.

15. The electronic device of claim 12, comprising a second implanted region including majority carrier dopants of the first type in a lateral top portion of the well region spaced apart from the transistor finger structure along the second direction, and a second conductive contact extending from the second implanted region to a metallization structure.

16. An electronic device, comprising:
a semiconductor layer having a side extending in a plane of orthogonal first and second directions and including majority carrier dopants of a first type;
a transistor finger structure extending longitudinally along the first direction and including a drain finger having opposite drain finger ends spaced apart from one another along the first direction in the semiconductor layer and including majority carrier dopants of a second type, and source fingers laterally spaced apart from opposite sides of the drain finger along the second direction in the semiconductor layer and including majority carrier dopants of the second type;
a buried layer including majority carrier dopants of a second type in the semiconductor layer and spaced apart from the side of the semiconductor layer along a third direction that is orthogonal to the first and second directions;
a deep trench isolation structure laterally surrounding the transistor finger structure in the semiconductor layer, the deep trench isolation structure extending through the semiconductor layer to a semiconductor substrate along the third direction; and
a deep well laterally surrounding a portion of the deep trench isolation structure and adjacent a portion of the buried layer in the semiconductor layer, the deep well connected by a metallization structure to the source fingers.

17. The electronic device of claim 16, comprising:
a first contact of the metallization structure connected to a portion of the deep well along the side of the semiconductor layer; and
a second contact of the metallization structure connected to one of the source fingers.

18. The electronic device of claim 16, wherein the transistor finger structure comprises a back- gate connected by the metallization structure to the deep well and to the source fingers.

19. The electronic device of claim 18, wherein the metallization structure includes a conductive metal feature having a first portion that extends along the first direction and second portions that extend from the first portion along the second direction to connect to the source fingers and to the back-gate.

20. The electronic device of claim 16, wherein the metallization structure includes a conductive metal feature having a first portion that extends along the first direction and second portions that extend from the first portion along the second direction to connect to the source fingers.
